(19) United States
(12) Patent Application Publication
(10) Pub. No.: US 2023/0398658 A1
(43) Pub. Date: Dec. 14, 2023

(54) DEBURRING UNIT AND CUTTING MACHINE

(71) Applicant: DISCO CORPORATION, Tokyo (JP)

(72) Inventors: Xiaoming QIU, Tokyo (JP); Fumiteru TASHINO, Tokyo (JP); Tomohiro KANEKO, Tokyo (JP)

(21) Appl. No.: 18/324,274

(22) Filed: May 26, 2023

(30) Foreign Application Priority Data
Jun. 9, 2022 (JP) 2022-093687

(51) Int. Cl. B24C 1/08

(52) U.S. Cl. CPC B24C 1/083

(57) ABSTRACT

A deburring unit removes burrs from a workpiece, the burrs being formed along kerfs cut by a cutting blade. The deburring unit includes a chuck table that holds the workpiece on a holding surface, an ultrasonic horn that emits ultrasonic waves from a lower surface, the lower surface facing an upper surface of the workpiece, a water film forming nozzle configured to form a water film such that the upper surface of the workpiece is covered in its entirety with the water film, and a controller. The controller is configured to cause the ultrasonic horn to come into contact at its lower surface with the water film formed by supply of water from the water film forming nozzle, such that ultrasonic vibrations propagate to the water film and remove the burrs formed in the kerfs of the workpiece.

### BACKGROUND OF THE INVENTION

### Field of the Invention

The present invention relates to a deburring unit for removing burrs from a workpiece with the burrs generated or formed along kerfs cut by a cutting blade, and also to a cutting machine including the deburring unit.

### Description of the Related Art

In a manufacturing process of semiconductor devices, for example, a front surface of a disk-shaped semiconductor wafer (hereinafter simply called a “wafer”) is defined into numerous rectangular regions by scribe lines (hereinafter called “streets”) arrayed in a grid pattern, and such devices as integrated circuits (ICs) or large scale integration circuits (LSIs) are formed in the individual rectangular regions. A plurality of semiconductor chips are then formed by cutting the wafer, on which the numerous devices have been formed, along the streets with a cutting blade called a “dicing saw” of a cutting machine (see, for example, Japanese Patent Laid-open No. 2018-160578).

As known well, burrs occur on edges of kerfs (cut grooves) formed in a wafer, when the wafer is cut with a cutting blade of a cutting machine. As leads and electrode pads of devices such as ICs are arranged across streets of a wafer in a plurality of rectangular regions defined by the streets, the cutting of the wafer along the streets with the cutting blade also results in cutting of the leads and electrode pads, so that burrs of the leads and electrode pads are generated on the edges of kerfs of the wafer.

In Japanese Patent Laid-open No. 2016-157722 and Japanese Patent Laid-open No. 2019-096759, cutting machines are hence proposed. These cutting machines are each configured such that, during cutting processing of a plate-shaped workpiece with a cutting blade, high-pressure water is ejected toward kerfs while the kerfs are formed, thereby removing burrs generated on the edges of the kerfs. According to such cutting machines, deburring can be performed concurrently with the cutting processing of a plate-shaped workpiece.

### SUMMARY OF THE INVENTION

With a cutting machine that removes burrs by ejecting high-pressure water toward kerfs while forming the kerfs during cutting processing of a plate-shaped workpiece with a cutting blade as proposed in Japanese Patent Laid-open No. 2016-157722 and Japanese Patent Laid-open No. 2019-096759, there is a problem that a large amount of high-pressure water is needed during the cutting processing.

The present invention therefore has as objects thereof the provision of a deburring unit, which can effectively remove burrs generated along kerfs on a workpiece, without using a large amount of high-pressure water, and a cutting machine including the deburring unit.

In accordance with a first aspect of the present invention, there is provided a deburring unit for removing burrs from a workpiece with the burrs formed along kerfs cut by a cutting blade. The deburring unit includes a chuck table that holds the workpiece on a holding surface thereof, an ultrasonic horn that emits ultrasonic waves from a lower surface thereof, the lower surface facing an upper surface of the workpiece held on the holding surface, a water film forming nozzle configured to supply water to the workpiece held on the holding surface and to form a water film that covers the upper surface of the workpiece in its entirety, and a controller. The controller is configured to cause the ultrasonic horn to come into contact at the lower surface thereof with the water film formed with the water supplied from the water film forming nozzle and to cause ultrasonic vibrations to propagate to the water film, to thereby remove the burrs formed along the kerfs.

In accordance with a second aspect of the present invention, there is provided a cutting machine including a cutting unit that cuts with a cutting blade a workpiece held on a holding surface of a chuck table, a moving mechanism that moves the chuck table in a cutting feed direction of the cutting blade, an ultrasonic horn having a lower surface that is facing an upper surface of the workpiece held on the holding surface of the chuck table, with a clearance therebetween, and a water film forming nozzle configured to supply water to the workpiece held on the holding surface and to form a water film that covers the upper surface of the workpiece in its entirety.

According to the present invention, the removal of burrs generated along kerfs on a workpiece is achieved by forming a water film over the entirety of an upper surface of the workpiece, causing the ultrasonic horn to come into contact at its lower surface with the water film, and allowing ultrasonic vibrations to propagate to the water film. The burrs can thus be efficiently and surely removed in a short period of time. Moreover, the removal of the burrs does not require ejection of high-pressure water toward the kerfs of the workpiece during the cutting processing of the workpiece, so that the deburring can be performed economically at low cost without wasting a large amount of high-pressure water.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view of a cutting machine according to an embodiment of the second aspect of the present invention, including a deburring unit according to an embodiment of the first aspect of the present invention;

FIG. 2 is a fragmentary exploded broken side view of the deburring unit illustrated in FIG. 1;

FIG. 3 is a cross-sectional view taken along line III-III of FIG. 2;

FIG. 4 is a broken side view illustrating how cutting processing of a workpiece is performed by the cutting machine illustrated in FIG. 1;

FIG. 5 is a perspective view of a cutting machine according to a modification of the embodiment of the second aspect of the present invention, which is provided in a transfer unit thereof with the deburring unit illustrated in FIG. 2;

FIG. 6 is a fragmentary broken perspective view of a cleaning unit including a deburring unit according to a first modification of the embodiment of the first aspect of the present invention;

FIG. 7 is a fragmentary side cross-sectional view illustrating operation of the deburring unit illustrated in FIG. 6;

FIG. 8 is a fragmentary broken perspective view of a cleaning unit including a deburring unit according to a second modification of the embodiment of the first aspect of the present invention; and

FIG. 9 is a fragmentary side cross-sectional view illustrating operation of the deburring unit illustrated in FIG. 8.

### DETAILED DESCRIPTION OF THE PREFERRED EMBODIMENTS

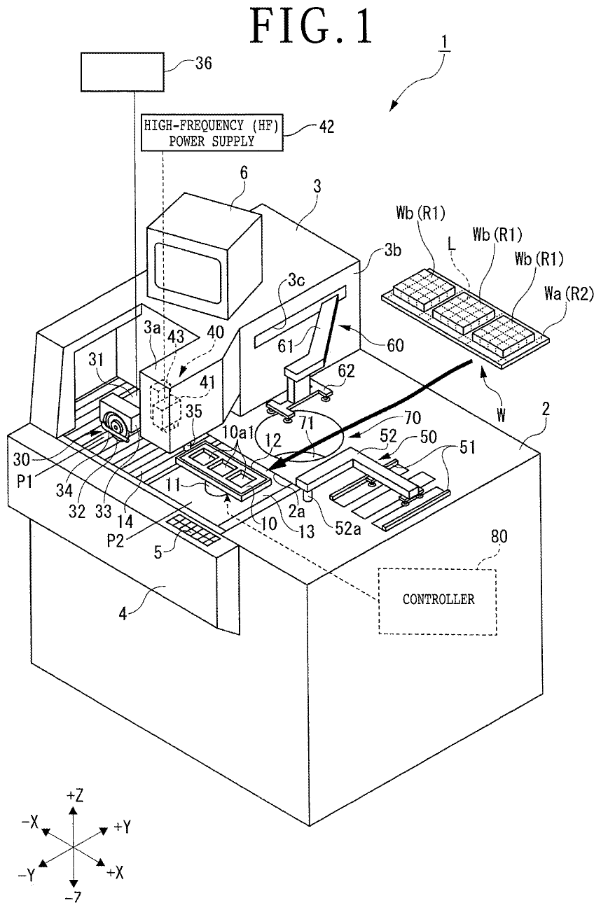

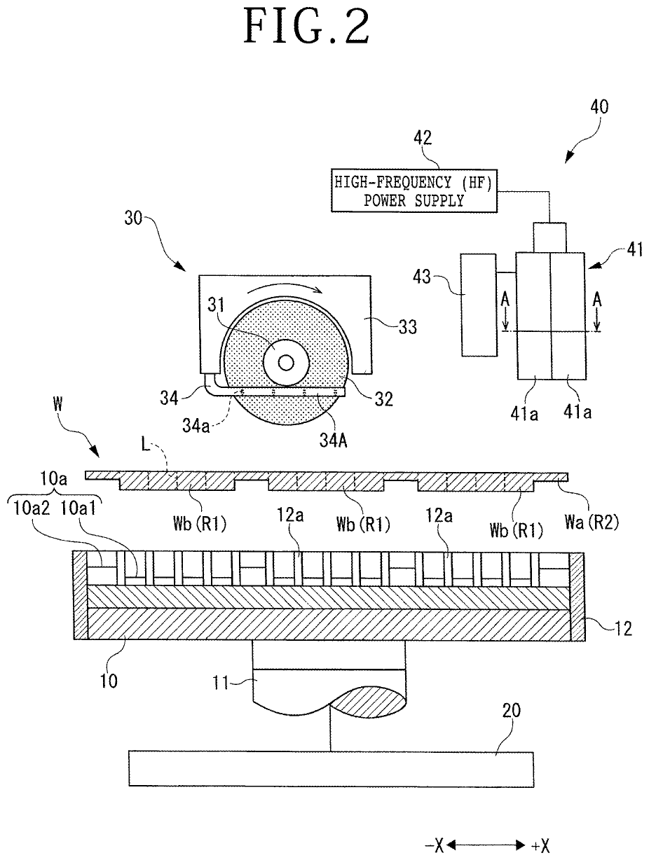

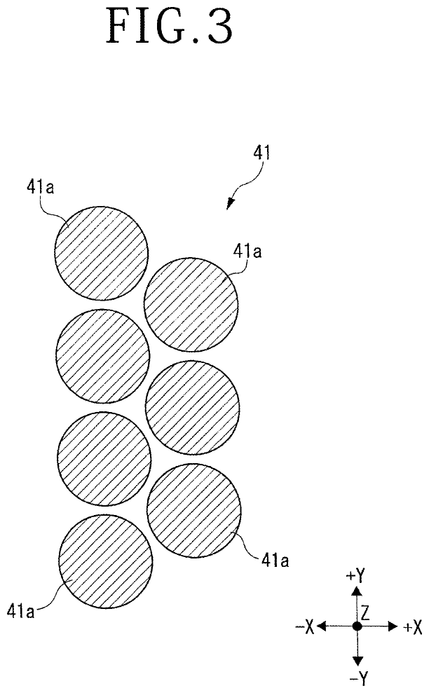

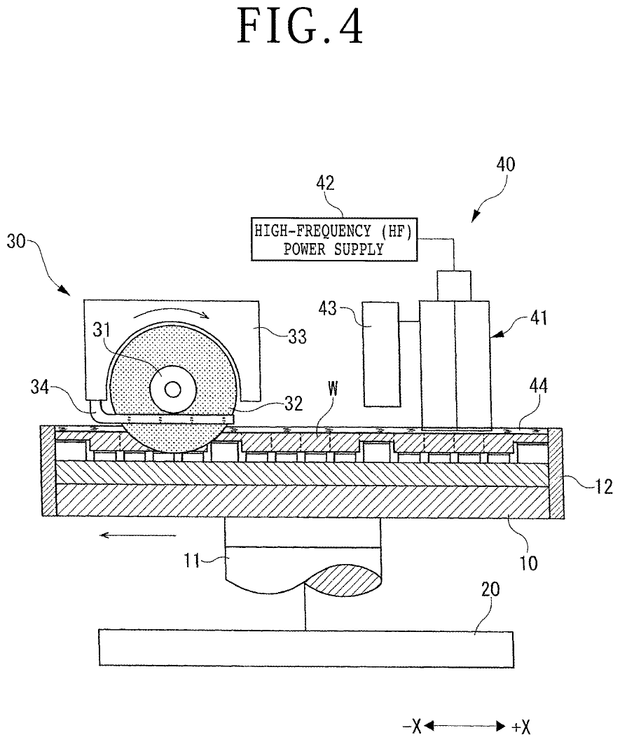

Embodiments of the first and second aspects of the present invention and first and second modifications of the embodiment of the first aspect will hereinafter be described in reference to the attached drawings. FIG. 1 is a perspective view of a cutting machine 1 according to the embodiment of the second aspect of the present invention, including a deburring unit 40 according to the embodiment of the first aspect of the present invention. FIG. 2 is a fragmentary exploded broken side view of the cutting machine 1, FIG. 3 is a cross-sectional view taken along line III-III of FIG. 2, and FIG. 4 is a broken side view illustrating how cutting processing of a plate-shaped workpiece W is performed by the cutting machine 1. In the following description, arrowed directions illustrated in FIG. 1 should each be interpreted to indicate an X-axis direction (left-right direction), a Y-axis direction (front-rear direction), and a Z-axis direction (up-down direction).

The cutting machine 1 illustrated in FIG. 1 is used for cutting the workpiece W, and as principal elements thereof, includes a chuck table 10 that holds the workpiece W, a moving mechanism 20 (see FIGS. 2 and 4) that moves the chuck table 10 in the X-axis direction (cutting feed direction), a cutting unit 30 that cuts the workpiece W held on the chuck table 10, the deburring unit 40 according to the embodiment of the first aspect of the present invention for removing burrs formed on the workpiece W by cutting with the cutting unit 30, a first transfer unit 50 and a second transfer unit 60 as transfer units that hold the workpiece W and transfer it to predetermined positions, a cleaning unit 70 that cleans the workpiece W obtained after cutting processing, and a controller 80.

Next, configurations of the chuck table 10, the moving mechanism 20, the cutting unit 30, the deburring unit 40, the first transfer unit 50, the second transfer unit 60, the cleaning unit 70, and the controller 80, all of which are the principal elements that make up the cutting machine 1, will hereinafter be described sequentially.

As illustrated in FIG. 1, the chuck table 10 is a member of a rectangular plate shape, and its upper surface makes up a holding surface 10a (see FIG. 2) that holds the workpiece W under suction. This chuck table 10 is movable along a length direction of a recess 2a that opens in an upper surface of a bed 2 (X-axis direction), and is supported in a rotatable manner about a vertical axial center. Described specifically, as illustrated in FIGS. 2 and 4, the chuck table 10 is horizontally attached to an upper end of a vertical rotating shaft 11, and the rotating shaft 11 is rotationally driven about its axial center by a rotating mechanism (not illustrated), whereby the chuck table 10 is horizontally rotated. Further, the chuck table 10, the rotating shaft 11, and the rotating mechanism (not illustrated) are reciprocally movable along the X-axis direction (cutting feed direction) by the moving mechanism 20 illustrated in FIGS. 2 and 4.

Here, the workpiece W, as illustrated in FIGS. 1 and 2, is a package substrate configured by integrally disposing a plurality (three in the example illustrated in the figures) of rectangular block-shaped protruding portions Wb side by side along a length direction on a front surface of a rectangular resin substrate Wa such that the protruding portions Wb protrude upward from the resin substrate Wa. The resin substrate Wa is configured, for example, of a poly chlorinated biphenyl (PCB) substrate. Areas of the workpiece W where the protruding portions Wb are disposed are device regions R1 for semiconductor devices, and a peripheral edge area other than these device regions R1 of the resin substrate Wa is a surplus region R2 having a small thickness. Each device region R1 is further defined or divided into a plurality of regions by lattice-patterned streets L, and a semiconductor device (not illustrated) is formed in each of these regions.

From the workpiece W configured as described above, the surplus region R2 is cut off as a cut margin by the cutting machine 1, and each device region R1 is cut along the streets L and thus divided into individual chips.

The workpiece W is not limited to a substrate with semiconductor devices formed thereon, and may be a metal substrate with light emitting diodes (LED) devices formed thereon, and further is not limited to a substrate obtained after the formation of devices thereon, and may be a substrate available before the formation of devices thereon. As the material of the protruding portions Wb of the workpiece W, epoxy resin, silicone resin, or the like is selected, for example, but any desired appropriate material can be used insofar as it can form the protruding portions Wb on the resin substrate Wa.

On the other hand, at an area of the holding surface 10a of the chuck table 10, the area corresponding to the protruding portions Wb of the workpiece W, a plurality (three in the example illustrated in FIGS. 1 and 2) of recessed portions 10a1 are similarly formed side by side along a length direction, as illustrated in FIGS. 1 and 2, such that the protruding portions Wb of the workpiece W fit therein. It is to be noted that the individual recessed portions 10a1 formed in the holding surface 10a of the chuck table 10 accommodate the corresponding protruding portions Wb therein when the workpiece W is held on the holding surface 10a of the chuck table 10 with the protruding portions Wb directed downward, and have a depth coincident with the height of the protruding portions Wb. As illustrated in FIG. 2, around the recessed portions 10a1 of the holding surface 10a of the chuck table 10, a support surface 10a2 is formed to support the surplus region R2 formed along a peripheral edge of the workpiece W. The holding surface 10a of the chuck table 10 is connected to a suction source (not illustrated) such as a vacuum pump.

In this embodiment, as illustrated in FIGS. 1, 2, and 4, a rectangular frame-shaped outer wall 12 is also disposed vertically upright around the chuck table 10 such that the outer wall 12 surrounds the chuck table 10 from outside. The outer wall 12 has a height set to such a value that a top surface of the outer wall 12 is located slightly above an upper surface of the workpiece W, in other words, a back surface of the resin substrate Wa, in a state in which the workpiece W is held on the holding surface 10a (see FIG. 2) of the chuck table 10 with the protruding portions Wb directed downward as illustrated in FIG. 4. At a plurality of locations of the outer wall 12, specifically at a plurality of locations corresponding to the streets L of the workpiece W, slits 12a are formed in a vertical direction as illustrated in FIG. 2. These slits 12a allow the cutting blade 32 to pass therethrough during cutting processing to be described later.

As illustrated in FIG. 1, the chuck table 10 is facing the recess 2a of the bed 2. Surroundings of this chuck table 10 are covered by a rectangular plate-shaped cover 13, and the recess 2a of the bed 2 is covered, on both (left and right) sides in the X-axis direction of the cover 13, by bellows-shaped retractable covers 14 that move together with the cover 13 in the X-axis direction to expand or retract. The recess 2a of the bed 2 is normally closed by the cover 13 and the retractable covers 14 wherever the chuck table 10 is located on the X-axis, so that the prevention of penetration of contaminants from the recess 2a into the bed 2 is ensured.

The moving mechanism 20 illustrated in FIGS. 2 and 4 serves to reciprocally move the chuck table 10 and the workpiece W held thereon under suction, in the X-axis direction (cutting feed direction) between a processing station P1 and a transfer station P2 (see FIG. 1) on the bed 2, and is configured with a known ball screw mechanism or the like although it is not illustrated in the figures and its detailed description is omitted.

A support stage 3 is disposed upright on a left end portion (an end portion in a −X-axis direction) of the bed 2, and the cutting unit 30 is supported on the support stage 3. At the processing station P1, this cutting unit 30 is arranged above the chuck table 10 that has moved to the processing station P1. The cutting unit 30 includes a spindle 31 that is arranged horizontally in the Y-axis direction (front-rear direction) and is rotatable, a spindle motor (not illustrated) that rotationally drives the spindle 31, the disk-shaped cutting blade 32 attached to a distal end of the spindle 31, and the like. In this embodiment, a washer blade formed by binding abrasive grits such as diamond with a binder material is used as the cutting blade 32, and an upper half portion of the cutting blade 32 is covered by a rectangular box-shaped blade cover 33.

Inside the blade cover 33, a portion of a cutting water nozzle 34 is accommodated. This cutting water nozzle 34 serves to eject cutting water as processing fluid toward the cutting blade 32 during cutting processing, and its tip portion 34A extends downward from the blade cover 33, is bent at right angle into an L-shape, and then extends in a +X-axis direction (rightward in FIG. 2) beside the cutting blade 32. In the tip portion 34A of the cutting water nozzle 34, a plurality of slits 34a (see FIG. 2) are formed opening toward the cutting blade 32. This cutting water nozzle 34 is connected to a water supply source (not illustrated).

As also illustrated in FIG. 1, an imaging unit 35 is supported on a lower portion of a cantilevered support portion 33a of the support stage 3.

The cutting unit 30 configured as described above is indexing fed in the Y-axis direction (front-rear direction) by an indexing feed mechanism 36 illustrated in FIG. 1, and is raised or lowered in the Z-axis direction (cut-in direction) by a lift mechanism (not illustrated). The lift mechanism is configured with a known ball screw mechanism or the like.

The deburring unit 40 according to the embodiment of the first aspect of the present invention serves to remove burrs (not illustrated) that have occurred along kerfs (cut grooves) formed in the workpiece W by the below-mentioned cutting processing of the workpiece W, and includes an ultrasonic horn 41 that emits ultrasonic waves from a lower surface thereof facing the upper surface of the workpiece W held on the chuck table 10, the above-described cutting water nozzle 34 that functions as a water film forming nozzle to form a water film 44 (see FIG. 4) over the entirety of the upper surface of the workpiece W by supplying water to the workpiece W held on the chuck table 10, and the controller 80.

As illustrated in FIG. 1, the above-described ultrasonic horn 41 is built in the cantilevered support portion 3a of the support stage 3, and as illustrated in detail in FIGS. 2 and 4, is arranged beside the cutting blade 32 in the X-axis direction (cutting feed direction). In this embodiment, the ultrasonic horn 41 is configured by arranging and integrating seven circular cylindrical horns 41a in the X-axis direction (in the left-right direction parallel to the holding surface 10a of the chuck table 10) as illustrated in FIG. 3. Described specifically, the ultrasonic horn 41 is configured by assembling and integrating four circular cylindrical horns 41a and three circular cylindrical horns 41a, which are arranged with a small clearance in the Y-axis direction (front-rear direction), in two rows in the X-axis direction (left-right direction). The ultrasonic horn 41 is not limited to the above-described configuration, and may be configured by assembling such circular cylindrical horns 41a in a single row or in three or more rows. Further, the ultrasonic horn 41 may be built in to cover the entirety of the upper surface of the workpiece W. Further, the ultrasonic horn 41 may have a rectangular cylindrical shape instead of having the circular cylindrical shape.

The ultrasonic horn 41 is electrically connected to a high-frequency (HF) power supply 42, and is raised or lowered in the Z-axis direction by a lift mechanism 43 illustrated in FIGS. 2 and 4. The lift mechanism 43 is configured with a known ball screw mechanism or the like. The lift mechanism 43 and the high-frequency power supply 42 are electrically connected to the controller 80, and are controlled by the controller 80.

During the cutting processing of the workpiece W, the controller 80 supplies water from the cutting water nozzle 34 used commonly as the water film forming nozzle, covers with water the entirety of the upper surface of the workpiece W held on the chuck table 10, to form the water film 44, causes the ultrasonic horn 41 to come into contact at the lower surface thereof with the water film 44, and then allows ultrasonic vibrations to propagate to the water film 44, thereby allowing the deburring unit 40 to perform its function of removing burrs generated along kerfs on the workpiece W. Details of the controller 80 will be described later.

As illustrated in FIG. 1, on an end portion in the +X-axis direction (right end portion) of the bed 2, a pair of guide rails 51 are arranged parallel to each other and extend in the Y-axis direction (front-rear direction). The paired guide rails 51 serve to temporarily place and position the workpiece W available before the cutting processing. Near the paired guide rails 51, the first transfer unit 50 is disposed to hold the workpiece W, which is temporarily placed on the guide rails 51, and transfer it to the chuck table 10. This first transfer unit 50 includes a first transfer arm 52 that is bent in a L-shape as seen in plan and is swingable about a vertical shaft 52a. The first transfer unit 50 is configured such that the workpiece W is held by a distal end portion of the first transfer arm 52.

As also illustrated in FIG. 1, on a side wall 3b of the support stage 3, a second transfer unit 60 is disposed to hold the cutting-processed workpiece W, and to transfer it to the cleaning unit 70. This second transfer unit 60 includes a second transfer arm 61 movable in the Y-axis direction (front-rear direction) along a guide slot 3c formed horizontally along the Y-axis direction (front-rear direction) in the side wall 3b of the support stage 3. The second transfer arm 61 is bent in an elbow shape as seen in plan, and holds the workpiece W by a transfer pad 62 attached to a distal end portion thereof.

The cleaning unit 70 is arranged at a substantially central area of the bed 2, and includes a disk-shaped cleaning table (spinner table) 71 and a cleaning water nozzle (not illustrated). The cleaning table 71 rotates at a predetermined speed about a vertical axial center with the cutting-processed workpiece W held thereon, and the cleaning water nozzle ejects cleaning water toward the workpiece W held on the cleaning table 71.

The controller 80 includes a central processing unit (CPU) that performs computation processing in accordance with a control program, memories such as a read only memory (ROM) and a random access memory (RAM), and the like. This controller 80 controls the rotating mechanism (not illustrated) that rotates the chuck table 10 about the axial center thereof, the spindle motor (not illustrated) that rotationally drives the spindle 31 of the cutting unit the indexing feed mechanism 36, the lift mechanism (not illustrated) that raises and lowers the cutting unit 30, the high-frequency power supply 42 that drives the ultrasonic horn 41 of the deburring unit the lift mechanism 43 (see FIGS. 2 and 4) that raises and lowers the ultrasonic horn 41, drive mechanisms (not illustrated) for the first transfer unit 50 and the second transfer unit 60, a rotating mechanism that rotates the spinner table 71 of the cleaning unit 70, and so on.

In the cutting machine 1 according to this embodiment, as illustrated in FIG. 1, an operation box 4 is attached to an end portion in a −Y-axis direction (front-side end portion) of the bed 2, an input unit 5 such as a keyboard is disposed on the operation box 4 to input various kinds of data, and a monitor unit 6 is arranged on the support stage 3 to display images captured by the imaging unit 35, cutting processing conditions for the workpiece W, and the like.

A description will next be made of operation of the cutting machine 1 configured as described above. When cutting processing of the workpiece W is performed by the cutting machine 1, the workpiece W is placed and positioned on the paired guide rails 51 illustrated in FIG. 1. The workpiece W so positioned is next held by the first transfer unit 50 and transferred to the chuck table 10 that stands by at the transfer station P2, and as illustrated in FIG. 2, is placed on the chuck table 10 with the front surface of the workpiece W directed downward. The protruding portions Wb of the workpiece W are then fitted in the recessed portions 10a1 formed in the holding surface 10a of the chuck table 10. When the holding surface 10a of the chuck table 10 is sucked by the suction source (not illustrated) in this state, the workpiece W is held under suction on the holding surface 10a of the chuck table 10.

At the processing station P1 illustrated in FIG. 1, on the other hand, after an image has been acquired by imaging the front surface of the workpiece W with imaging unit 35, one of the streets L along which cutting is to be performed is detected by pattern matching based on the image. Following the detection of the street L of the workpiece W along which cutting is to be performed, as described above, the position in the Y-axis direction (indexing direction) of the cutting blade 32 is determined, and the position in the Y-axis direction of the cutting blade 32 is aligned with the position of the street L of the workpiece W along which cutting is to be performed, by the indexing feed mechanism 36.

From the state described above, the cutting blade 32 is lowered by a predetermined cut-in amount by the lift mechanism (not illustrated) for the cutting unit 30 while being rotationally driven at a high speed, and at the same time, the chuck table 10 and the workpiece W held thereon are moved in a −X-axis direction by the moving mechanism 20 illustrated in FIGS. 2 and 4. In addition, cutting water is supplied from the water supply source (not illustrated) to the cutting water nozzle 34, and is ejected toward the cutting blade 32 from the slits 34a (see FIG. 2) formed in the tip portion 34A of the cutting water nozzle 34.

At the processing station P1, the workpiece W held on the chuck table 10 is then cut along the streel L by the cutting blade 32 while being fed with the cutting water from the cutting water nozzle 34. At this time, the cutting water ejected from the cutting water nozzle 34 and used for lubrication and cooling of the cutting blade 32 accumulates in a space inside the outer wall 12 surrounding the workpiece W, and as illustrated in FIG. 4, the water film 44 of a small thickness is formed over the entirety of the upper surface of the workpiece W. At this time, the ultrasonic horn 41 has been lowered by the lift mechanism 43, and as illustrated in FIG. 4, has come into contact at the lower surface thereof with the water film 44. When the ultrasonic horn 41 is actuated by the high-frequency power supply 42, ultrasonic vibrations propagate from the ultrasonic horn 41 to the water film 44, thereby reliably removing burrs that have occurred along kerfs (cut grooves) formed in the workpiece W through the cutting by the cutting blade 32, by ultrasonic vibrations of the water film 44. In this embodiment, the removal of the burrs that have occurred along the kerfs on the workpiece W is concurrently performed while cutting processing of the workpiece W is performed, so that the burrs can be efficiently and surely removed in a short period of time. Further, the removal of the burrs is performed using the cutting water ejected from the cutting water nozzle 34 toward the cutting blade 32, and unlike in the related art, it is hence no longer necessary to eject high-pressure water in addition to cutting water toward the kerfs of the workpiece W. Deburring can thus be performed economically at low cost without wasting a large amount of high-pressure water.

After the above-described cutting processing has been performed on the workpiece W along all the streets L in one direction, the chuck table 10 and the workpiece W held thereon are rotated by 90° by the rotating mechanism (now illustrated), followed by similar cutting processing along the streets L in the other direction orthogonal to the streets L along which the cutting has already been completed. Upon completion of the cutting along all the streets L of the workpiece W, a plurality of chips are obtained with devices formed individually thereon.

After the completion of the above-described cutting processing of the workpiece W by the cutting unit 30, the workpiece W is held and transferred by the second transfer unit 60 from the chuck table 10 to the cleaning unit 70. The workpiece W transferred to the cleaning unit 70 is then placed on the cleaning table 71, and is held under suction on the cleaning table 71 by the suction source (not illustrated). The cleaning table 71 and the workpiece W held thereon are next rotationally driven at a predetermined speed about the vertical axial center by the rotating mechanism (not illustrated), and cleaning water is ejected from the cleaning water nozzle (not illustrated) toward the workpiece W, whereby cutting debris stuck on the workpiece W is cleaned off and removed.

With the cutting machine 1 according to this embodiment, cutting processing is performed on the workpiece W through a series of processing as described above. As described above, the burrs that have occurred along the kerfs (cut grooves) formed in the workpiece W during the cutting processing are surely removed in a short period of time by ultrasonic vibrations of the water film 44 by the ultrasonic horn 41, the water film 44 being formed over the entirety of the upper surface of the workpiece W with the cutting water ejected from the cutting water nozzle 34 toward the cutting blade 32 during the cutting processing of the workpiece W.

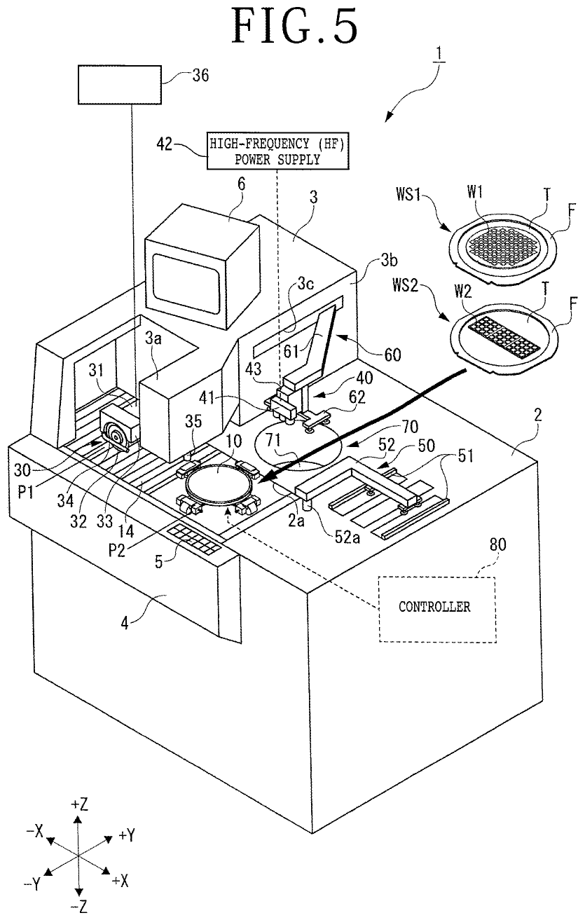

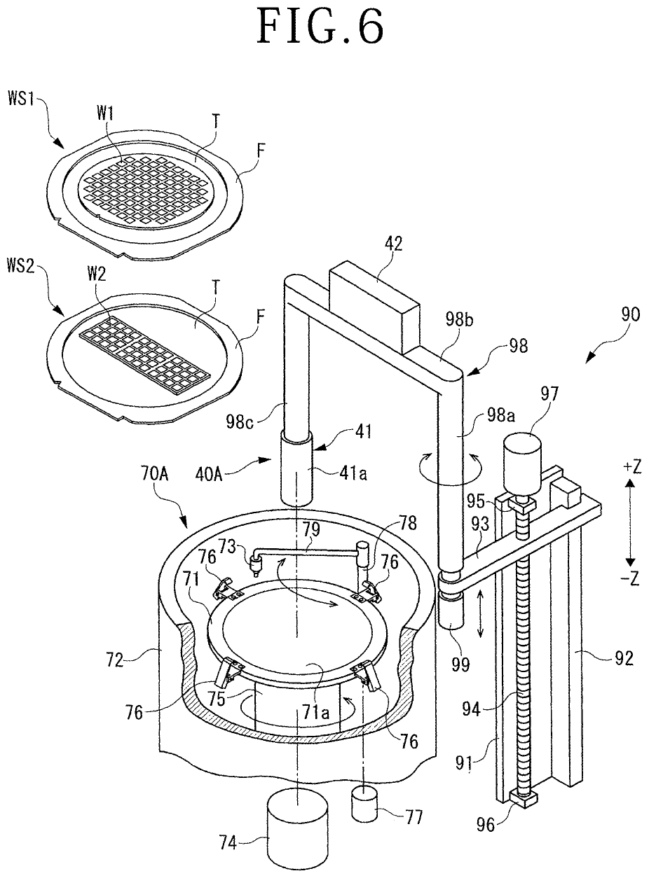

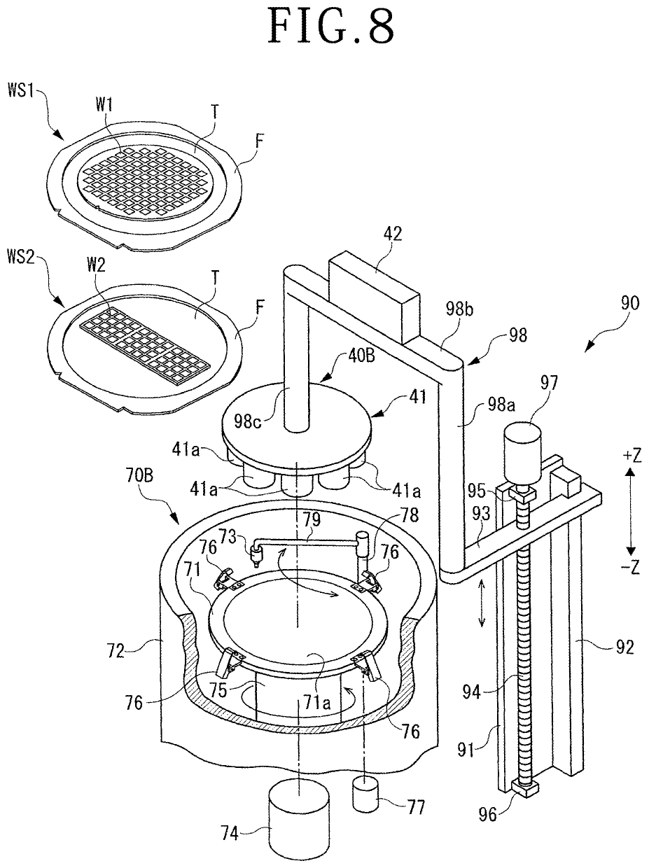

The above embodiment adopts the configuration in which the water film 44 is formed over the entirety of the upper surface of the workpiece W during cutting processing of the workpiece W held on the chuck table 10 and the water film 44 is ultrasonically vibrated by the ultrasonic horn 41. FIG. 5 is a perspective view of a cutting machine 1 according to a modification of the above-described embodiment. As illustrated in FIG. 5, the ultrasonic horn 41 may be attached to the transfer pad 62 of the second transfer unit 60, and the deburring unit 40 may be configured with the ultrasonic horn 41 and a cleaning water nozzle (not illustrated). In this case, the cleaning water nozzle is concurrently used as a water film forming nozzle. Burrs that have occurred along kerfs on the workpiece W can thus be removed by a water film being formed over the entirety of the upper surface of the workpiece W with cleaning water ejected from the cleaning water nozzle and the water film being ultrasonically being vibrated with the ultrasonic horn 41 kept in contact at the lower surface thereof with the water film. The cutting machine 1 illustrated in FIG. 5 is used to hold a disk-shaped workpiece W1 (or rectangular workpiece W2) of a workpiece set WS1 (or WS2), which is illustrated in FIGS. 6 and 8 and will be described later, on a disk-shaped chuck table 10, and cut the workpiece W1 (or W2).

At the cleaning unit 70, the same advantageous effects as mentioned above can be obtained when the ultrasonic horn 41 is attached to the transfer pad 62 of the second transfer unit 60 as described above. Now, different examples of a deburring unit disposed in a cleaning unit will hereinafter be described as a first modification and a second modification.

<First Modification>

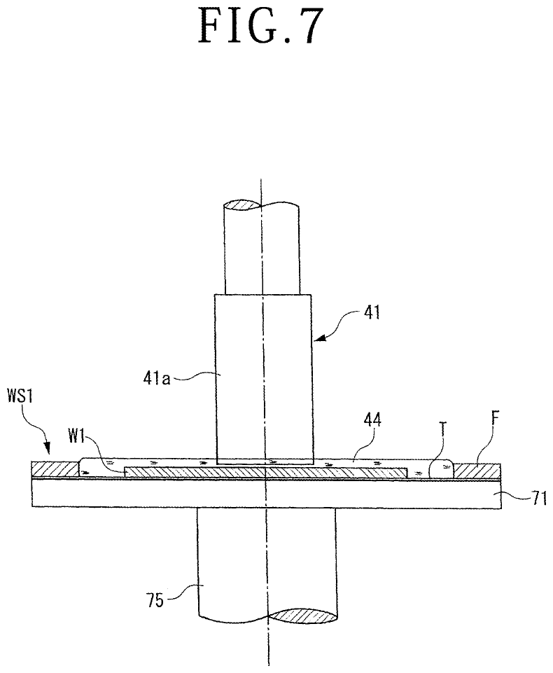

FIG. 6 is a fragmentary broken perspective view illustrating a deburring unit 40A as the first modification of the deburring unit 40 according to the embodiment of the first aspect of the present invention, and FIG. 7 is a fragmentary side cross-sectional view illustrating operation of the deburring unit 40A illustrated in FIG. 6.

A cleaning unit 70A illustrated in FIG. 6 includes an upwardly open, drum-shaped casing 72, and a disk-shaped cleaning table (cleaner table) 71 and a cleaning water nozzle 73, both of which are accommodated in the drum-shaped casing 72. Here, the cleaning table 71 is horizontally attached to an upper end of a rotating shaft 75 that is rotationally driven about a vertical axial center by an electric motor 74 as a rotary drive source, and the workpiece set WS1 or WS2 is held on an upper surface of the cleaning table 71 by four clamps 76. Described specifically, the four clamps 76 are attached at equal angular pitches (90° pitches) in a peripheral direction to an outer peripheral portion of the cleaning table 71, and the workpiece set WS1 or WS2 placed on a holding surface 71a of the cleaning table 71 is fixed and held on the holding surface 71a of the spinner table 71 by the four clamps 76.

Further, the cleaning water nozzle 73 is attached to a distal end of an arm 79 extending horizontally from an upper end of a vertical shaft 78 swingably driven by an electric motor 77, and cleaning water is supplied from a cleaning water supply source (not illustrated) to the cleaning water nozzle 73.

In the workpiece set WS1, the disk-shaped workpiece (wafer) W1 and a ring-shaped frame F disposed around the workpiece W1 are integrated by a tape T bonded thereto. In the workpiece set WS2, on the other hand, the rectangular workpiece W2 and a ring-shaped frame F disposed around the workpiece W2 are integrated by a tape T bonded thereto. Each workpiece W1 or W2 is defined at a front surface (upper surface in FIG. 6) thereof into a number of rectangular regions by a plurality of streets arrayed in a grid pattern, and devices such as ICs or LSIs are formed in the individual rectangular regions. When the workpiece W1 or W2 with the numerous devices formed thereon as described above is cut along streets, burrs occur on the workpiece W1 or W2. These burrs are removed by the deburring unit 40A.

The deburring unit 40A according to this first modification includes an ultrasonic horn 41 having a lower surface that is facing an upper surface of the workpiece W1 (or W2) of the workpiece set WS1 (or WS2) is held on the holding surface 71a of the cleaning table 71, with a clearance therebetween, and the cleaning water nozzle 73 as the water film forming nozzle that forms the water film 44 (see FIG. 7) over the entirety of the upper surface of the workpiece W1 (or W2) of the workpiece set WS1 (or WS2) held on the cleaning table 71.

The above-described ultrasonic horn 41 includes a single circular cylindrical horn 41a, and this ultrasonic horn 41 is arranged on a central axis of the holding surface 71a of the cleaning table 71, and can be raised or lowered in the Z-axis direction by a lift mechanism 90 illustrated in FIG. 6. The lift mechanism 90 includes a slider 93 that is movable up and down in the Z-axis direction along a guide rail 92 attached to a base plate 91 disposed vertically upright, and a vertical ball screw shaft 94 is threadedly inserted through the slider 93.

The above-described ball screw shaft 94 is supported in a rotatable manner at upper and lower ends thereof on the base plate 91 via bearings 95 and 96, and is connected at the upper end thereof to an electric motor 97 as a rotary drive source.

When the electric motor 97 is actuated and the ball screw shaft 94 is rotated in the lift mechanism 90 configured as described above, the slider 93 that is in threaded engagement with the ball screw shaft 94 is moved up or down along the guide rail 92 so that the ultrasonic horn 41 raised or lowered in the Z-axis direction together with a gantry swing arm 98 attached to the slider 93.

On one end portion in a length direction of the slider 93 arranged in the horizontal direction, the swing arm 98 is supported in a swingable manner. A vertical turning shaft portion 98a of this swing arm 98 is supported on the slider 93 in a turnable manner, and an electric motor 99 is attached as a rotary drive source to a lower end of a portion of the turning shaft 98a, the portion extending through the slider 93.

From an upper end of the turn ng shaft portion 98a of the swing arm. 98, a horizontal arm portion 98b extends horizontally, and on the horizontal arm portion 98h, a high-frequency (HF) power supply 42 is arranged to actuate the ultrasonic horn 41. Further, a vertical portion 98c extends vertically downward from an end portion in a length direction of the horizontal arm portion 98h of the swing arm 98, and the ultrasonic horn 41 is attached to a lower end of the vertical portion 98c.

In the cleaning unit 70A including the deburring unit 40A configured as described above, the electric motor 99 is actuated, the swing arm 98 is caused to horizontally swing centering around the turning shaft portion 98a, and the ultrasonic horn 41 attached to the vertical portion 98c of the swing arm 98 is positioned on a central axis of the workpiece W1 (or W2) of the workpiece set WS1 (or WS2) as illustrated in FIG. 7. From this state, cleaning water is then ejected from the cleaning water nozzle 73 toward the workpiece W1 (or W2), and as illustrated in FIG. 7, a water film 44 is formed, with the cleaning water ejected from the cleaning water nozzle 73, over the entirety of the upper surface of the workpiece W1 (or W2) of the workpiece set WS1 (or WS2) held on the holding surface 71a of the spinner table 71. From this state, the ultrasonic horn 41 is lowered by the lift mechanism 90. When the ultrasonic horn 41 comes into contact at the lower surface thereof with the water film 44 formed over the entirety of the upper surface of the workpiece W1 (or W2), the ultrasonic horn 41 is driven by the high-frequency power supply 42, so that ultrasonic vibrations propagate from the ultrasonic horn 41 to the water film 44. Burrs that have occurred on the workpiece W1 (or W2) are thus surely removed by the ultrasonic vibrations of the water film 44.

In this first modification, the burrs that have occurred on the workpiece W1 (or W2) can be efficiently and surely removed in their entirety at once in a short period of time in the cleaning unit 70A. As the removal of the burrs is performed using the cleaning water ejected from the cleaning water nozzle 73, it is no longer necessary, unlike in the related art, to eject high-pressure water in addition to cleaning water toward the workpiece W1 (or W2). Deburring can thus be performed economically at low cost without wasting a large amount of high-pressure water.

The cleaning of the workpiece set. WS1 (or WS2) by the cleaning unit 70A is performed, as in the related art, by ejecting cleaning water from the cleaning water nozzle 73 toward the workpiece set WS1 (or WS2) while rotating the cleaning table 71 and the workpiece set WS1 (or WS2) held thereon at a predetermined speed.

<Second Modification>

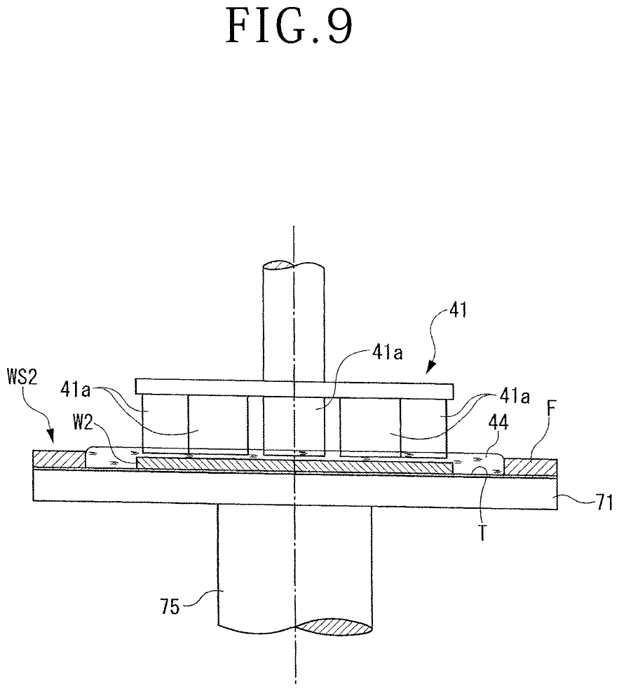

FIG. 8 is a fragmentary broken perspective view of a deburring unit 40B as the second modification of the deburring unit 40 according to the embodiment of the first aspect of the present invention, and FIG. 9 is a fragmentary side cross-sectional view illustrating operation of the deburring unit 40B illustrated in FIG. 8. In these figures, the same elements as those illustrated in FIGS. 6 and 7 are identified by the same reference numerals, and their repeated descriptions are omitted.

In this second modification, an ultrasonic horn 41 disposed in the deburring unit 40B is configured by assembling and integrating a plurality (ten in the example illustrated in FIGS. 8 and 9) of circular cylindrical horns 41a in an annular pattern, and this ultrasonic horn 41 is located above a central area of the holding surface 71a of the spinner table 71.

In a cleaning unit 70B including the deburring unit 40B according to this second modification, cleaning water is ejected from the cleaning water nozzle 73 toward the workpiece W2 (or W1), and as illustrated in FIG. 9, a water film 44 is formed, with the cleaning water ejected from the cleaning water nozzle 73, over the entirety of the upper surface of the workpiece W2 (or W1) of the workpiece set WS2 (or WS1) held on the holding surface 71a of the cleaning table 71. From this state, the ultrasonic horn 41 is lowered by the lift mechanism 90. When the ultrasonic horn 41 comes into contact at the lower surface thereof with the water film 44 formed over the entirety of the upper surface of the workpiece W2 (or W1), the ultrasonic horn 41 is driven by the high-frequency power supply 42, so that ultrasonic vibrations propagate from the ultrasonic horn 41 to the water film 44. Burrs that have occurred on the workpiece W2 (or W1) are thus surely removed by the ultrasonic vibrations of the water film 44.

In this second modification, the burrs that have occurred on the workpiece W2 (or W1) can also be efficiently and surely removed in their entirety at once in a short period of time in the cleaning unit 70B as in the first modification. As the removal of the burrs is performed using the cleaning water ejected from the cleaning water nozzle 73, it is unnecessary to eject high-pressure water in addition to cleaning water toward the workpiece W21 (or W1). Deburring can thus be performed economically at low cost without wasting a large amount of high-pressure water.

The cleaning of the workpiece set WS2 (or WS1) by the cleaning unit 70B is also performed, as in the related art, by ejecting cleaning water from the cleaning water nozzle 73 toward the workpiece set WS2 (or WS1) while rotating the cleaning table 71 and the workpiece set WS2 (or WS1) held thereon at predetermined speed.

Moreover, the practice of the present invention should not be limited to the embodiments and modifications described above, and various modifications can obviously be made within the scope of the technical concept described in the claims, specification, and drawings.

The present invention is not limited to the details of the above-described preferred embodiments. The scope of the invention is defined by the appended claims and all changes and modifications as fall within the equivalence of the scope of the claims are therefore to be embraced by the invention.

What is claimed is:

1. A deburring unit for removing burrs from a workpiece with the burrs formed along kerfs cut by a cutting blade, comprising:
a chuck table that holds the workpiece on a holding surface thereof;
an ultrasonic horn that emits ultrasonic waves from a lower surface thereof, the lower surface facing an upper surface of the workpiece held on the holding surface;
a water film forming nozzle configured to supply water to the workpiece held on the holding surface and to form a water film such that the upper surface of the workpiece is covered in its entirety with the water film; and
a controller,
wherein the controller is configured to cause the ultrasonic horn to come into contact at the lower surface thereof with the water film formed with the water supplied from the water film forming nozzle and to cause ultrasonic vibrations to propagate to the water film, to thereby remove the burrs formed along the kerfs.

2. The deburring unit according to claim 1, wherein the ultrasonic horn is configured with a plurality of circular cylindrical horns integrally arranged in a direction parallel to the holding surface as seen in plan.

3. A cutting machine comprising:
a cutting unit that cuts with a cutting blade a workpiece held on a holding surface of a chuck table;
a moving mechanism that moves the chuck table in a cutting feed direction of the cutting blade;
an ultrasonic horn having a lower surface that is facing an upper surface of the workpiece held on the holding surface of the chuck table, with a clearance therebetween; and
a water film forming nozzle configured to supply water to the workpiece held on the holding surface and to form a water film such that the upper surface of the workpiece is covered in its entirety with the water film.

4. The cutting machine according to claim 3, wherein the ultrasonic horn is arranged beside the cutting blade in the cutting feed direction, and the water film forming nozzle is configured to also function as a cutting water nozzle that supplies cutting water to the cutting blade.

5. The cutting machine according to claim 3, further comprising:
a cleaning unit including a cleaning table that holds the workpiece obtained after cutting processing and a cleaning water nozzle that ejects cleaning water toward the workpiece held on the cleaning table,
wherein the water film forming nozzle is configured to also function as the cleaning water nozzle.

6. The cutting machine according to claim 3, further comprising:
a transfer unit that loads and unloads the workpiece onto and from the chuck table,
wherein the ultrasonic horn is disposed on the transfer unit.
